(19) United States
(12) Patent Application Publication
(10) Pub. No.: US 2025/0183683 A1
(43) Pub. Date: Jun. 5, 2025

(54) BATTERY MODULE COMPRISING PARALLEL BRANCHES AND VOLTAGE SENSING ASSEMBLY

(71) Applicant: SEM AB, ÅMÅL (SE)

(72) Inventor: Bo Bijlenga, ÅMÅL (SE)

(73) Assignee: SEM AB, ÅMÅL (SE)

(21) Appl. No.: 18/840,760

(22) PCT Filed: Feb. 9, 2023
(86) PCT No.: PCT/EP2023/053143

§ 371 Date: Aug. 22, 2024

(30) Foreign Application Priority Data
Feb. 25, 2022 (SE) 2250264-5

(51) Int. Cl. H02J 7/00; G01R 31/3835; G01R 31/396; H01M 10/42; H01M 10/44; H01M 10/48

(52) U.S. Cl. CPC H02J 7/00304; G01R 31/3835; G01R 31/396; H01M 10/4235; H01M 10/4257; H01M 10/441; H01M 10/482; H02J 7/0013; H02J 7/0047; H01M 2010/4271; H01M 2200/00

(57) ABSTRACT

A battery module (2) and a battery pack (100) are disclosed. The battery module (2) comprises a control circuit (1), a first node (3) and a second node (4) for charging and/or discharging, at least two first branches (71-7M). Each first branch (71-7M) comprises a respective plurality of battery cells (C11-CN1, . . . , C1M-CNM) of the battery cells (C11-CNM), and a respective first switch (Q11-Q1M). The battery module (2) comprises one or more second branches (81-8M) having respective second switches (Q21-Q2M). The control circuit (1) is provided with a number of connection lines (V1-VN). Each connection line (V1-VN) is arranged to parallelly connect a respective set (C11-C1M, C21-C2M, . . . , CN1-CNM) of corresponding battery cells (C11-CNM) to each other via a respective controllable over-current protecting component (S11-S1M, . . . , SN1-SNM). Said each corresponding battery cell (C11-CNM) is comprised in a respective first branch (71-7M) of said at least two first branches (71-7M). The corresponding battery cells are corresponding to each other in that of a respective second count of battery cells towards the first or second node (3, 4) from said each corresponding battery cell in the respective first branch (71-7M) is equal.

### TECHNICAL FIELD

Embodiments herein relate to battery management by means of e.g., electrical circuits for battery cells, battery packs, battery modules, strings of battery cells and related circuitry, or the like. In particular, various embodiments of a battery module and a battery pack comprising one or more battery modules according to the various embodiments are disclosed.

### BACKGROUND

Conventional high voltage battery packs are normally built from a large number of series connected battery cells, to reach the intended voltage, typically in a range from about 400 volts to about 800 volts, but also lower and higher voltage can be used depending on application. In order to reach the intended Ah rating, a number of battery cells are also often connected in parallel. This means that a battery pack often is arranged as a matrix of cells connected in parallel and in series. From handling point of view, the battery pack is often also arranged into battery modules, with a certain number of cells in series and a number of cells in parallel in each battery module. In this manner, one battery module may easily be replaced with another battery modules in case of a failure in said one battery module. Such battery modules are series connected to each other to form a battery pack. Often such a battery module is designed with 12-16 cells in series, but both lower and higher numbers of cells in series can be used. In battery modules comprising Li ion battery cells, a monitoring circuit is normally connected to each module. The monitoring circuit normally monitors the cell voltage of each of the series-connected cells (same voltage of all parallel connected cells). Also, the temperature is monitored of all battery cells or only a few cells or one cell in each module. Cell monitoring is used to ensure that the cells are kept within a safe operating range and to ensure that none of the cells are over-charged or under-charged. The safe operating range can be that the cells are monitored to be operating e.g., below a certain temperature, below a certain current through it or the like. The monitoring circuit can also be used to activate resistor switched cell balancing within the module, to keep the series-connected battery cells in the module at approximately the same SOC (State Of Charge). In case the SOC is too high in one cell, one switch of a number of series connected switches, will be closed and current will pass the switch and a couple of resistors in series with the switch and slowly discharge the battery cell or the group of parallel-connected cells, to reduce SOC.

In reconfigurable battery packs, a number of battery cells in series, here called a string of cells, can be connected to a pair of switches, which can direct a current of the reconfigurable battery pack through the string of cells or direct the current such that it passes the string of cells without going through them. There are also other possible circuit arrangements, such as e.g., four switches configured in a full bridge, also called an H-bridge, with the possibility also to reverse the current direction through the battery cells.

The unit consisting of a string of cells, with a monitoring circuit, combined with at least one pair of switches with control electronics is in the following called just a battery module or a bypassable battery module, to indicate that the current can either be directed through the string of cells or directed to pass by the string of cells, such that the current is either passing or not passing, i.e. going through or going past them without going through them, the string of cells in the module. The switches can change state either at very low frequency, such as 0.001-10 Hz, which can be called on/off control, or at much higher frequency such as 1-500 kHz in Pulse Width Modulation (PWM) mode, like in a DC (Direct Current)/DC-converter. Then the current is passing an inductor to even out current fluctuations. Sometimes, the current passing the string of cells can be controlled to be a variable fraction of the current of the battery pack. Either methods, or combined, can be used to achieve both a controllable voltage across the battery pack and to make it possible to do active cell balancing, balancing e.g., the State Of Charge, SOC or the temperature between the different string of cells in the different bypassable battery modules. In this context, reference is made to publicly available WO2021094010 and WO2021094011.

In battery packs in general and especially for Li ion batteries, there is a risk that the battery can catch fire. Such an event is normally starting in one cell. Especially overcharging but also overtemperature are examples of reasons for such an event. Also ageing of cells can increase this risk. This type of failure can be caused by a number of factors, such as battery cell ageing, e.g., due to Li plating, leading to internal short circuit of the battery cell in at least one point, resulting in a fast energy release, followed by fire if the energy release is large enough. There are a number of other factors as well, such as e. g mechanical damage or built-in manufacturing weaknesses, that can increase the risk for fast energy release and fire. To conclude, Li ion cells have a certain risk for going into a condition, where at least a part of the stored energy in one battery cell is converted to heat, resulting in overtemperature, leading to thermal runaway, gas release and in some cases even fire. A disadvantage is that such an event can-if the energy release is large enough—be spread to adjacent cells and to the entire battery pack.

### SUMMARY

An object may be to eliminate, or at least reduce, one or more the abovementioned disadvantages and/or problems.

According to a first aspect, there is provided a battery module. The battery module comprises a control circuit configured to monitor battery cells of the battery module and to control switches of the battery module. The battery module thus comprises battery cells and switches. The battery module comprises a first node and a second node for charging and/or discharging of the battery module.

Furthermore, the battery module comprises at least two first branches that are parallelly connected between the first and second nodes.

Each first branch of said at least two first branches is arranged to be capable of connecting the first and second nodes, e.g., to each other, by means of a respective first switch of the switches. As an example, when the respective first switch is on, the first and second nodes are connected and when the respective first switch is off, the first and second nodes are disconnected, at least with respect to the respective first branch in which the respective first switch is included.

Said each first branch comprises a respective plurality of battery cells of the battery cells, a respective first branch over-current protecting component, and the respective first switch. The respective plurality of cells, the respective first branch over-current protecting component and the respective first switch are connected in series, e.g., with each other.

The battery module further comprises one or more second branches arranged to be capable of connecting the first and second node by means of one or more second switches of the number of switches. Each second branch of said one or more second branches comprises a respective second switch of said one or more second switches. Again, as an example, when the respective second switch is on, the first and second nodes are connected and when the respective second switch is off, the first and second nodes are disconnected, at least with respect to the respective second branch in which the respective second switch is included.

Moreover, the control circuit is provided with a number of connection lines, such as connection wires or the like, corresponding to at least a first count of the respective plurality of battery cells.

Each connection line of the number of connection lines is arranged to parallelly connect a respective set of corresponding battery cells via a respective cell over-current protecting component for each corresponding battery cell of the respective set of corresponding battery cells. As an example, the battery module may comprise the number of connection lines, wherein each connection line of the number of connection lines may connect the control circuit to each one of the corresponding battery cells via the respective cell over-current protecting component. Said each corresponding battery cell of the respective set of corresponding battery cells is comprised in a respective first branch of said at least two branches.

Additionally, the corresponding battery cells of the respective set of corresponding battery cells are corresponding to each other in that a respective second count of battery cells towards the first and/or second node from said each corresponding battery cell in the respective first branch is equal, e.g., to each other. As an example, the corresponding cells of the respective set of corresponding battery cells are corresponding to each other e.g., in terms of their position within their respective plurality of battery cells. Said their respective position may be calculated as a number of cells between the corresponding cell under observation and the first node and/or the second node.

In some embodiments, said one or more second branches comprise at least two respective second branches. Said at least two respective second branches comprise a respective second branch over-current protecting component connected in series with the respective second switch of said at least two second branches. In this manner, it may be ensured that the battery module may be operated normally in case one of the respective second switches fails to short circuit. Therefore, when the respective first switch is closed, the respective second branch over-current protecting component will open due to that the respective plurality of cells are put in short circuit, since the respective second switch has failed and can thus not be opened. The respective second branch over-current protecting component in series with the shorted respective second switch has opened since the short circuit current from all the different first branches with strings of cells will be passing the failed second switch and the respective second branch over-current protecting component, such as a fuse, in series with the failed second switch.

In some embodiments, the control circuit is provided with a further connection line that is connected to each first cell of the respective plurality of cell. Said each first cell is closest to the first node among the cells of the respective plurality of battery cells. In this manner, voltage measurements over the battery cells may be implemented, e.g., independently of a location of a grounded connection. This embodiment, and other embodiments, is equally applicable to the further aspect mentioned below.

In some embodiments, the respective cell over-current protecting component is embodied by one or more of a fuse, a resettable fuse, an automatic circuit breaker, a resistor with positive temperature coefficient, a current limiting diode, a resistor or a so called smart semiconductor based IC circuit or failsafe switch, which at low current has low resistance but at higher currents becomes current limiting, i.e. after tripping to open state, in which current is limited by the component, when a threshold for current/voltage/power is reached, or the like.

In some embodiments, said at least two first branches comprise at least three first branches. In case of a failure, the energy dissipated to the remaining cells will be less as explained in the detailed description below.

In some embodiments, the respective plurality of battery cells C11-CN1, . . . , C1M-CNM, the respective first branch over-current protecting component F11-F1M, and the respective first switch Q11-Q1M of the first branch 71 may be arranged in one of the following orders or similar orders, when starting from the first node 3 and ending at the second node 4 or vice versa:
the respective plurality of battery cells C11-CN1, . . . , C1M-CNM, the respective first branch over-current protecting component F11-F1M, the respective first switch Q11-Q1M, which may be a preferred embodiment,
the respective plurality of battery cells C11-CN1, . . . , C1M-CNM, the respective first switch Q11-Q1M, the respective first branch over-current protecting component F11-F1M,
the respective first branch over-current protecting component F11-F1M, the respective first switch Q11-Q1M, the respective plurality of battery cells C11-CN1, . . . , C1M-CNM,
the respective first branch over-current protecting component F11-F1M, the respective plurality of battery cells C11-CN1, . . . , C1M-CNM, the respective first switch Q11-Q1M,
the respective first switch Q11-Q1M, the respective plurality of battery cells C11-CN1, . . . , C1M-CNM, the respective first branch over-current protecting component F11-F1M,
the respective first switch Q11-Q1M, the respective first branch over-current protecting component F11-F1M, the respective plurality of battery cells C11-CN1, . . . , C1M-CNM,

This means that there are six basic configurations according to combinatoric algorithms, i.e., 3*2*1=6.

However, according to further embodiments, the respective first branch over-current protecting component F11-F1M and/or the respective first switch Q11-Q1M may be connected between any two battery cells of the respective plurality of battery cells C11-CN1, . . . , C1M-CNM. The number of combinations will then be equal to the factorial of a sum of the number of battery cells plus two, where “plus two” is caused by counting the switch and the respective first branch over-current protecting component. In these embodiments, the control circuit may be provided with additional connection lines for purposes of more accurate measurement of voltage over the battery cells. In this manner, any voltage over e.g., the first branch over-current protecting component and/or the respective first switch may be excluded from the measurement of the cell voltage. This embodiment is equally applicable to the aspects below.

The same or similar reasoning and considerations applies for the second branch as applicable for the various embodiments herein and further aspects below. Typically, the respective first branch over-current protecting component and the respective first switch are located at the same circuit board and in this case, they will be located adjacent to each either.

As mentioned in the background section, in case of direct parallel connection of cells, i.e., without the respective cell over-current protecting component or similar, a type of failure that may occur is that one cell fails into a short circuit. A problem may then be that all parallel connected cells will dissipate their energy into that short circuit cell. As a result, there will be a large initial energy release into that short circuit cell, which will be more difficult to stop or reduce, as compared to if only the energy in one cell is released into the short circuit. An advantage with the respective cell over-current protecting component is hence that such energy release into the short circuit cell is at least reduced. Therefore, at least some of the embodiments herein mitigate, or even eliminate, this type of failure.

Furthermore, at least some embodiments herein provide a solution for how one battery module of a battery pack can be designed, i.e., in terms of how switches, over-current protecting components, fuses, cells, etc. are connected to each other, to reduce consequences for various single faults events inside the battery module. It is here assumed that the battery module comprises both series connected and parallelly connected battery cells in the manner disclosed herein. It is also assumed that the battery module is equipped with controllable switches, such as the respective first and second switches, to connect or bypass the string of cells, such as the respective plurality of battery cells. Further, it is also assumed that the current through the battery module is so large, that multiple of controllable switches or transistors in parallel is typically needed to conduct the current during normal operation of the battery module. This means that even though the first and second switch are referred to as in the singular, one or both of them may be embodied by a plurality of switches.

When introducing controllable switches into the battery module, there is also a risk that the switches can fail. Such switches can fail into a short circuit, which gives a risk for that the switches can short circuit a string of battery cells, causing a fast energy release, with risk of fire. There are different ways to protect a pair of switches from causing such a short circuit, using for example transistor drivers with built-in short circuit protection. This is normally done by having a short circuit protection circuit that detects that one of the switches has failed into a short circuit. The short circuit protection circuit will as next step turn-off the switch that is still functional, to prevent such a fast energy release. Alternatively, an over-current protecting component, such as a fuse, can be used as protection for short circuits. The two variants can also be combined in such way that the short circuit protection circuit acts as a primary protection, and the over-current protecting component acts as a secondary protection, to reduce the risk for such a failure, that can lead to an external short of a string of battery cells.

The embodiments herein provide a battery module of a battery pack with increased fault tolerance. An advantage is that a risk for catastrophic failures, such as a fire in case of single faults, is reduced.

Some embodiments give advantages in terms of the possibility to operate the battery pack even if the battery pack includes one or more faulty battery modules, e.g., with one or more short circuit cells and/or one or more short circuit switches. That is, the battery pack can be operated until the faulty battery module can be exchanged or repaired at next scheduled service, without severe degradation in terms of performance.

At certain faults also part of battery module will be possible to operate, but with reduced capacity after a single fault, with only a small or negligible impact to the customer or user. For example, one switch in series with certain respective plurality of battery cells of a particular first branch may be turned off, i.e., no current goes through the certain respective plurality of battery cells, while other parts, such as respective plurality of battery cells of other first branches than said particular first branch, are operating, i.e., contributing to voltage/current of the battery pack. This may be beneficial e.g., when one or more cells of said particular first branch has failed to short circuit. With at least some embodiments herein, other cells of said particular first branch will then, as mentioned, be able to contribute to the output of the battery pack, despite that the first branch over-current protecting component of the particular first branch typically may have opened. Said other cells contribute by feeding energy via the respective cell over-current protecting component into parallel cells for which their respective first switch is closed. These faults, if they happen, can also be detected by a so-called battery management system (BMS), which also typically controls and monitors the aforementioned control circuit.

Some type of single faults will be described in more detail herein:
Short circuit of a battery cell
Short circuit in one of the switches (e.g., the respective first and/or second switch) or reverse conducting diode, resulting in that the switch and diode is always conducting in both directions.

Other failure modes exist. The list above is not intended to be exhaustive. Thanks to that the battery module according to at least some embodiments herein handles one or more of the failure modes, it is said to be a fault tolerant battery module.

A purpose of the various embodiments herein is to reduce negative impact of a single fault situation, such as the ones mentioned directly above or other fault situations, in order to make it possible to detect the fault and to reduce the risk for that the battery pack and/or battery module is not operatable after such a single fault.

In addition, battery cells and switches, such as transistors, and more of the battery module according to at least some embodiments herein includes various other components such as current limiters or fuses, resistors, control electronics including drivers to drive the controllable switches. These circuits are not described in detail here for simplicity.

Even though, the embodiments above are fully functional and provide a plurality of advantages, a further object may be to provide a further improved battery module.

Thus, according to a second aspect, there is provided a battery module that comprises a control circuit configured to monitor battery cells of the battery module and to control switches of the battery module. The battery module comprises a first node and a second node for charging and/or discharging of the battery module.

Furthermore, the battery module comprises at least two first branches that are parallelly connected between the first and second nodes.

Each first branch of said at least two first branches is arranged to be capable of connecting the first and second nodes, e.g., to each other, by means of a respective first switch of the switches. As mentioned, as an example, when the respective first switch is on, the first and second nodes are connected and when the respective first switch is off, the first and second nodes are disconnected, at least with respect to the respective first branch in which the respective first switch is included.

Said each first branch comprises a respective plurality of battery cells of the battery cells, and the respective first switch. The respective plurality of cells and the respective first switch are connected in series, e.g., with each other.

Moreover, the battery module comprises one or more second branches arranged to be capable of connecting the first and second nodes by means of one or more second switches of the switches. Each second branch of said one or more second branches comprises a respective second switch of said one or more second switches. As mentioned, as an example, when the respective second switch is on, the first and second nodes are connected and when the respective second switch is off, the first and second nodes are disconnected, at least with respect to the respective second branch in which the respective second switch is included.

Additionally, the control circuit is provided with a number of connection lines corresponding to at least a first count of the respective plurality of battery cells.

Each connection line of the number of connection lines is arranged to parallelly connect a respective set of corresponding battery cells to each other via a respective controllable over-current protecting component for each corresponding battery cell of the respective set of corresponding battery cells. As an example, the battery module may comprise the number of connection lines, wherein each connection line of the number of connection lines may connect the control circuit to each one of the corresponding battery cells via the respective controllable over-current protecting component. Said each corresponding battery cell is comprised in a respective first branch of said at least two first branches.

The corresponding battery cells of the respective set of corresponding battery cells are corresponding to each other in that of a respective second count of battery cells towards the first and/or second node from said each corresponding battery cell in the respective first branch is equal, to each other. As already mentioned, as an example, the corresponding cells of the respective set of corresponding battery cells are corresponding to each other e.g., in terms of their position within their respective plurality of battery cells. Said their respective position may be calculated as a number of cells between the corresponding cell under observation and the first node and/or the second node.

Thanks to the cell over-current protecting component, embodiments herein enable accurate and efficient measurement of voltages of the battery cells of the battery module. Therefore, the battery module is said to be a battery module enabling cell voltage measurement.

In some embodiments, the control circuit is configured to send a respective control signal to a corresponding set of respective controllable over-current protecting components. The corresponding set of respective controllable over-current protecting components corresponds to said each first branch in that the corresponding set of respective controllable over-current protecting components comprises those respective controllable over-current protecting components for which said each corresponding battery cell is included in said each first branch. In this manner, all of the controllable switches in a respective first branch may be efficiently controlled, i.e., set to an open state, a closed state or the like.

In some embodiments, the control circuit is configured to receive a number of indications relating to voltage over each battery cell in a particular first branch by being configured to set the respective controllable over-current protecting component in said particular first branch to allow current through the respective controllable over-current protecting component, and set the respective controllable over-current protecting component in other first branches but said particular first branch to open whereby current through the respective controllable over-current protecting component is stopped.

In some embodiments, the control circuit is configured to repeat the setting of the respective controllable over-current protecting component in said particular first branch and the setting of the respective controllable over-current protecting component in other first branches but said particular first branch for said each first branch, e.g., comprising said particular first branch.

In some embodiments, the respective controllable over-current protecting component is configured to autonomously enter a latched state, in which the respective controllable over-current protecting component is set to an open state, when a threshold value relating to current through the respective controllable over-current protecting component and/or relating to voltage over the respective controllable over-current protecting component is reached or exceeded. In the open state, the respective controllable over-current protecting component may be open and/or present a high impedance such that no current or only a very small current may pass through the respective controllable over-current protecting component.

In some embodiments, the control circuit is configured to send a reset signal to the respective controllable over-current protecting component, wherein the reset signal instructs the respective controllable over-current protecting component to enter a closed state. In the closed state, the respective controllable over-current protecting component may be closed and/or present a low impedance such that current may easily pass through the respective controllable over-current protecting component.

In some embodiments, said one or more second branches comprise at least two respective second branches. Said at least two respective second branches comprise a respective second branch over-current protecting component connected in series with the respective second switch of said at least two second branches. Advantages and benefits of this embodiment is provided in the detailed description.

In some embodiments, said at least two first branches comprise at least three first branches. Advantages and benefits of this embodiment is provided in the detailed description.

In some embodiments, said each first branch comprises a respective first branch over-current protecting component, such a first fuse or the like as disclosed herein.

Again, it is emphasized that one or more of the embodiments according to the first aspect may be applied to the second aspect as well.

According to a further aspect, there is provided a battery pack comprising a battery module according to any one of the aspects and/or embodiments herein. The battery pack may be a re-configurable battery pack, because the configuration in terms of battery cells that contributes to a desired output voltage and/or output current of the battery pack may be re-configured, e.g., the number of cells may be dynamically changed, e.g., during charging and/or discharging.

For each of the aspects and embodiments above, further advantages and benefits will be apparent from the detailed description.

### BRIEF DESCRIPTION OF THE DRAWINGS

The various aspects of embodiments disclosed herein, including particular features and advantages thereof, will be readily understood from the following detailed description and the accompanying drawings, which are briefly described in the following.

FIG. 1 is a circuit diagram illustrating an exemplifying battery system according to state of the art including two or more series-connected battery modules of a battery pack.

FIG. 2 is a circuit diagram illustrating another exemplifying battery system according to state of art, showing two or more series-connected battery modules, where each battery module has two or more parallel connected battery cells and/or two or more parallel connected controllable switches.

FIG. 3 is a circuit diagram illustrating exemplifying battery modules according to some embodiments herein.

FIG. 4 is a circuit diagram illustrating other exemplifying battery modules according to some embodiments herein.

FIG. 5 is a circuit diagram illustrating further exemplifying battery modules according to some embodiments herein.

FIG. 6 is a circuit diagram illustrating yet another exemplifying battery modules according to some embodiments herein.

FIG. 7 is a circuit diagram illustrating still other exemplifying battery modules according to some embodiments herein.

FIG. 8 is a schematic block diagram, illustrating exemplifying battery pack according to some embodiments herein.

### DETAILED DESCRIPTION

Throughout the following description, similar reference numerals have been used to denote similar features, such as nodes, modules, circuits, parts, items, switches, controllable switches, over-current protecting components, controllable over-current protecting components, fuses, cells, elements, units or the like, when applicable.

As used herein, the terms “cell”, “battery cell” or the like are used interchangeably and refers to a battery cell, such as an Li Ion cell, etc., that typically is included in a string of cells.

As used herein, the term “switch” may refer to an electronic switch, a switch with diode, a transistor, a semiconductor switch, a MOSFET (Metal Oxide Semiconductor Field Effect Transistor) or JFET (junction-gate field-effect transistor) transistor with an internal or external reverse conducting diode or the like. The switch is normally controlled by a control signal to set a state of the switch to e.g. open state, closed state or the like.

As used herein, the terms “string of battery cells”, “string of cells” and “plurality of battery cells”, “plurality of cells” have been used interchangeably. The terms shall be understood to refer to a set of battery cells. This means that the set comprises battery cells that are connected in series with each other, typically the set includes more than one battery cells, such as 12-16 battery cells or as required per the specific application of the battery pack. Other components may or may not be connected in series before, after and/or in-between the battery cells in series.

As used herein, the term “operatable” may refer to those cells of the battery module and/or battery pack that are contributing to output current/voltage of the battery module and/or the battery pack.

As used herein, the term “control circuit” or the like may refer to a cell supervisory controller, a cell module controller or the like, for control and/or supervision of the battery cells in each battery module. The control circuit according to the examples herein is also configured to control, e.g., by sending of control signals, various switches, such as the first and second switch, the controllable switch and the like, as described herein.

As used herein, the term “control unit” or the like may refer to a battery pack controller or the like for controlling the configuration of the battery pack.

As used herein, the term “control system” or the like may refer to a battery management system or the like. The control system typically comprises the control circuit and the control unit.

As used herein, the terms “open switch”, “opening switch”, “turn off switch”, “switch is off”, or the like refers to that a switch is set to an open state, or off state, in which current cannot pass through the switch, i.e., the circuit is open, except for that current can still pass a reverse conducting diode of the switch. In the open state of the switch, the impedance of the switch is “high”.

As used herein, the terms “close switch”, “closing switch”, “turn on switch”, “switch is on”, or the like refers to that a switch is set to a closed state, or on state, in which current can pass through the switch in both directions at a low resistance, i.e., the circuit is closed. In the closed state of the switch, the impedance of the switch is “low”.

As used herein, the terms “open state” and “high impedance/resistance state” may have been used interchangeably.

As used herein, the terms “closed state” and “low impedance/resistance state” may have been used interchangeably.

Throughout the present disclosure, the terms “controllable switch” and “over-current protecting component” have been used. The state, such as open state or closed state, of a controllable switch is controlled by a control signal. The state of an over-current protecting component is controlled autonomously by the over-current protecting component based on current through it, voltage over it, and/or power dissipated in it. The state of the over-current protecting component may in some examples also be controlled by a control signal. The over-current protecting component may thus sometimes be a controllable over-current protecting component, such as a self-protected electronic switch or the like as disclosed herein. Alternatively, the over-current protecting component may be a non-controllable over-current protecting component, such as a fuse, resettable fuse or the like as disclosed herein. Generally, the over-current protecting component is configured to autonomously enter the open state when current through it, voltage over it, and/or power dissipated in it, has reached or exceeded a related threshold value, e.g., according to requirements and specification of the over-current protecting component or the related threshold value may be configurable, e.g., by/from another component, such as a controller, e.g., a control circuit 1 mentioned below.

In addition, an over-current protecting component may be resettable, which means that the over-current protecting component may autonomously enter the closed state, e.g., when current through it, voltage over it, and/or power dissipated in it, is considered to be sufficiently low.

A controllable over-current protecting component's state may also be controlled by a control signal, in addition to that the open state may be entered autonomously and, optionally, the closed state may be entered autonomously when the component is resettable.

Moreover, an over-current protecting component is associated with a threshold value for current through, voltage over and/or power dissipated in it. This means that the threshold value is related to over-current that the component protects against. The over-current protecting component enters the open state when the threshold value is reached or exceeded. As an example, an over-current protecting component may be configured to enter the open state based on the threshold value, such as when the threshold value is exceeded or reached, alternatively when the threshold value is undershot (or sunk below) or reached, depending on technical application.

Furthermore, the terms “latched”, “latched state” or the like refers that a component is latched in an open state, i.e., only a control signal, if available, may cause the component to enter the closed state again.

| | Control | Autonomously | |
|---|---|---|---|
| | signal for | (without | |
| | setting | control signal) | Autonomously |
| | open/closed | enter open | enter closed |
| Component | state | state | state |
| Controllable switch | Yes | optional | optional |
| Over-current | No | Yes | If component is |
| protecting | | | resettable then |
| component | | | yes, otherwise no |
| Controllable over- | Yes | Yes | If component is |
| current protecting | | | latched then no, |
| component | | | otherwise possibly |
| (Controllable self- | | | yes preferably |
| protected switch) | | | with hysteresis. |
| Fuse | No | Yes | No |
| Resettable fuse | No | Yes | Yes |

As used herein, the term “battery pack current” refers to a current of the battery pack, such as an output current. The current of the battery pack typically passes through those battery modules that contribute to the output current and/or output voltage of the battery pack. The current of the battery pack may occur due to charging or discharging.

As used herein, the term “battery pack voltage” refers to a voltage over the battery pack. The voltage over the battery pack is a sum of respective voltages over each battery module. The voltage may occur due to charging or discharging.

As used herein, the terms “parallel connected” and “parallelly connected” have been used interchangeably to refer to any two components that are connected in parallel.

As used herein, the term “line” typically refers to a wire, an electrical connection, a conducting wire or the like. Preferably, the line is assumed to be a perfect conductor with no resistance. The line may include one or more branches.

As used herein, the term “signal” refers to an analog or digital signal, such as a message, a high/low signal, a high/medium/low signal, a serial communication bus containing the signal information or the like. The signal is typically transmitted on a wire, a line or the like. However, the signal may also or alternatively be wirelessly transmitted using any known wireless technology or any suitable future wireless technology.

As used herein, the term “node” may refer to a node at which electrical connection may be obtained, such as a terminal, an input/output terminal, a port, a connector, a conducting pin or the like.

As used herein, the term “branch” has its conventional meaning within electronic circuit analysis. That is to say, a branch refers to a portion of an electronic circuit, e.g., between two defined potential points.

As used herein, the term “direct parallel connection” refers to when battery cells are connected in parallelly to each other directly, e.g., the anodes of two battery cells are connected directly without any components, or any components that gives advantages as herein, between the anodes and similarly for the cathodes, i.e., the cathodes of the two battery cells are connected directly without any components between the cathodes.

As used herein, the term “indirect parallel connection” refers to when battery cells are connected in parallelly to each other indirectly, e.g., the anodes of two battery cells are connected indirectly with components, such as cell over-current protecting components, controllable switches or the like, between the anodes. It may here be noted that between any two battery cells, when considering their indirect parallel connection, there will be two components, such as two cell over-current protecting components, two controllable switches or the like.

The terms “direct parallel connection” and “indirect parallel connection” are contrasting to each other and may even been considered to be opposites.

As used herein, the term “over-current protecting component” refers to a component that normally is conducting a current, at a low series resistance, i.e., the component is in a closed state. At a certain current, after a certain time at a certain current, at a certain voltage across the component, after a certain time at a certain voltage across the component, at a certain power or/and after a certain time at a certain power (such as the i2t value of a fuse), the component will change resistance, often abruptly, to reduce the current through the component to zero, or at least to a low value close to zero. This may be referred to as that the component enters an open state. The component typically has a high resistance or high impedance in the open state. For a fuse, no or very little current may pass through it in the open state. The component may be a fuse, a resettable fuse, such as a PPTC (polymeric positive temperature coefficient) device, a fusible resistor, a fusible wire, a self-protected normally conducting transistor, such as a self-protected NMOS (n-channel metal-oxide semiconductor) transistor which often is both current limiting and temperature limited to limit the power dissipation of the component in the open state, a smart IC circuit with such mentioned current protecting characteristics, a current limiting diode, a current circuit breaker with built-in overcurrent protection, a resistor with a large positive temperature coefficient etc. For a fuse, a fusible resistor and a fusible wire, the change to high resistance or high impedance state, similar to open state, is permanent. For many of the other examples of the over-current protecting component, the component may automatically go to the low resistance and conducting state, similar to closed state, again if the fault such as a shorted circuit which caused the overcurrent is removed.

Throughout the present disclose three over-current protecting components are described. These are distinguished as follows. “first branch over-current protecting component” or “first over-current protecting component” is located in the first branch. “second branch over-current protecting component” or “second over-current protecting component” is located in the second branch. “cell over-current protecting component” or “third over-current protecting component” is provided for each battery cell of the battery module. The expressions before “over-current protecting component” shall be understood as labels, whereby it shall be understood which over-current protecting component that is referred to.

The cell over-current protecting component may be embodied with or without control input. The control input may set the component in either the low resistance state or in the high resistance state in case there is no overcurrent. The control signal may in this case also be used to reset the component from a latched high resistance state into a low resistance state again.

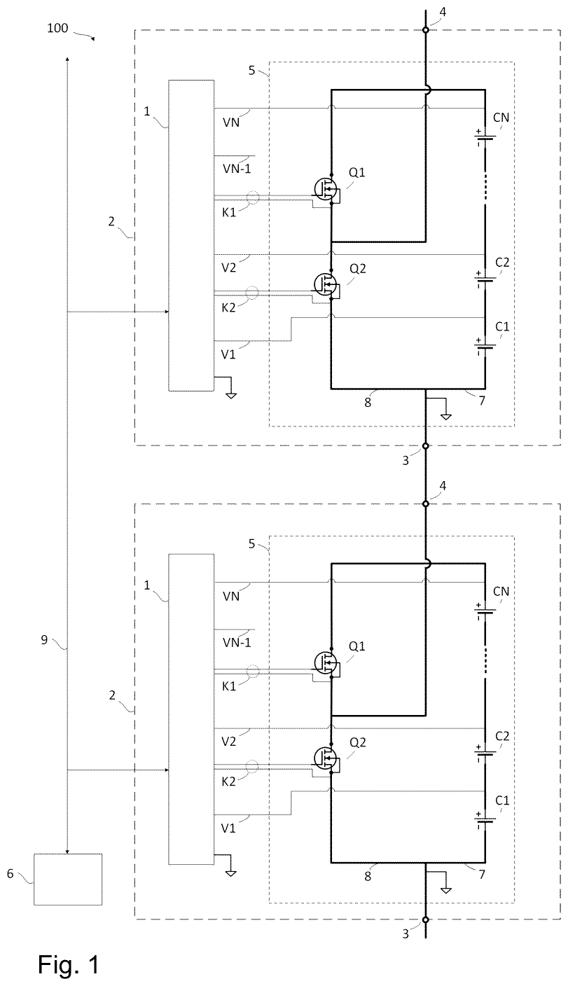

In FIG. 1, a first battery module 2 and a second battery module 2 are series connected to each other, to form a battery pack according to prior art. Normally, many more series connected battery modules will be used than two, to form the battery pack in order to achieve a desired high output voltage, such as 400V to 1200V or the like, from the battery pack. Typically, the number of battery modules is in the range of 8-30, but also lower or higher numbers are possible, depending on the desired output voltage of the battery pack and the nominal voltage of the string of cells. The battery pack may be a so called re-configurable battery pack with controllable output voltage. This means that a configuration of the battery pack in terms of battery cells that contributes to a desired output voltage and/or output current of the battery pack may be re-configured, e.g., the number of cells may be dynamically changed, e.g., during charging and/or discharging.

Each of the first and second battery modules, both denoted 2, includes a first controllable switch Q1 and a second controllable switch Q2, with the purpose of directing the battery current either 1) through the plurality of battery cells, C1-CN by opening the second controllable switch Q2 and closing the first controllable switch Q1 or 2) past (bypassing of current) the plurality of battery cells by opening of the first switch Q1 and closing the second switch Q2.

In each battery module 2, there is a first node 3 and a second node 4. The first and/or second nodes 3,4 may be output terminals, connectors, potential points at a conducting busbar or the like, by means of which one battery module is connected to the next one. Between the nodes 3, 4, there is a first branch 7 and a second branch 8. The first branch 7 comprises the plurality of battery cells C1, C2, . . . CN, and the first controllable switch Q1, where all these components are series connected to each other. The number of battery cells in the string of cells C1-CN are typically 12-16 cells, but also lower or higher number of series connected battery cells can be used.

In order to measure cell voltage over each cell C1-CN, a control circuit 1 may be included in the battery module 2. The control circuit 1 includes cell monitoring circuits, connected to the plurality of battery cells. The cell monitoring circuits may be IC circuits with interface circuits used to measure cell voltages. As mentioned, the control circuit 1, normally also handles resistor switched cell balancing of the cells, to even out differences in State Of Charge (SOC) between the cells. The control circuit also normally measures the temperature of at least one battery cell or at other points in the battery module. The first and second controllable switches Q1 and Q2 are also controlled by the control circuit 1 through the control lines K1 and K2, respectively.

Normally, the control circuit 1 of each battery module 2 are connected to each other and to a common battery pack control unit 6, such as a battery management system (BMS), through a control line 9. The control line 9 can be of different types, such as an isolated serial bus in daisy chain configuration, as a wireless transmission line using radio technology, as an isolated serial bus, fiber optic communication or other types. The communication line is often bidirectional, so data can be transferred in both directions, both from and to the common control unit 6 and sometimes also between the control circuits 1 in the different battery modules. The control unit 6 optionally together with the control circuits 1 may be referred to as a BMS. For a re-configurable battery pack, the control line 9 typically also includes information that can be used to control the first and second switch Q1, Q2 in each battery module 2 of the battery pack and the control line 9 can include several control signals.

Still referring to FIG. 1, in series with the string of cells C1-CN, there is a first semiconductor switch Q1 that can connect the string of cells to the remainder of the battery pack 100. In the second branch 8, there is a second controllable switch Q2 that can bypass the battery pack current, which thus does not go through the battery cells, if it is turned on, i.e., closed such that the battery pack current runs through the second branch 8 without battery cells. The battery pack current runs through the first and second nodes 3, 4 of all battery modules 2, forming the battery pack. The first and second controllable switches Q1 and Q2 are controlled by a control circuit 1 through the control lines K1 and K2. That is, the control circuit 1 is configured to send control signals on the control lines K1, K2 in order to open and close the first and second switches Q1, Q2. If Q1 is turned on and Q2 is turned off, the current through the battery module will pass through the cells and the cells are included in the total current path of the battery pack. This state is called on-state of the battery module. If Q1 is turned off and Q2 is turned on, the current is bypassed from the string of cells, and the cells do not contribute to the total voltage of the battery pack anymore. The total voltage of the battery pack is a sum of respective voltages over each battery module. This state is in the following called bypass state of the battery module. There is also a third state, called disable state of the battery module, where both Q1 and Q2 are turned off. In disable state, the current only can flow through reverse diodes included in the controllable switches Q1 and Q2. In case Q1 and Q2 is a MOSFET transistor or a JFET transistor, such a reverse conducting diode is normally part of the component, but the reverse conducting diode can also be external from the switch.

If all battery modules of the battery pack go to disable state at the same time, the current through the battery pack will be interrupted and go to zero.

The known battery pack, schematically illustrated in FIG. 1, has some problems in terms of what impact a single failure would have on the possibility to operate the battery pack. If for example transistor Q1 fails into a short circuit and transistor Q2 is turned on, the string of cells will be shorted by the two transistors. This can lead to a very high current and fast energy release of the stored energy in the cells. There is risk for that both transistors Q1 and Q2 will fail, first to a short circuit followed by risk for melting, evaporation, arcing and for starting a fire. There are known ways to reduce the risk for this to happen, by adding a short circuit protection circuit that can detect short circuit currents. Such a circuit can for example detect that transistor Q1 has failed and turn off transistor Q2 before the current has risen to dangerous levels. After this is done, the battery current will flow through the failed transistor Q1. However, a transistor that is failing into a short circuit can have higher resistance and power dissipation than a fully working transistor which is in the closed state. Thus, the safest way would in this case be to stop the current in the battery pack by disabling all other battery modules.

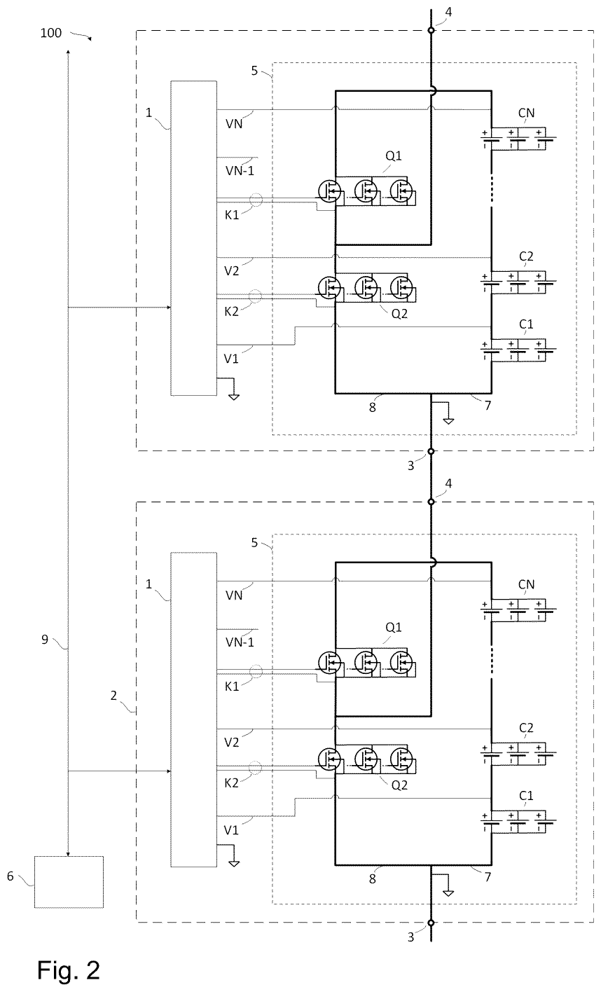

In FIG. 2, a first battery module 2 and a second battery module 2, which are series connected to each other to form a battery pack, are shown again. In this case, the plurality of cells C1, C2, . . . , CN comprises not only a number of series connected cells but also a number of directly parallel connected cells, on each level. Expressed differently, there is a main string of battery cell groups, where each battery cell groups comprises parallel connected battery cells. This means that—in comparison to the strings of cells in FIG. 1 each cell of such string is in FIG. 2 represented by a group of parallelly connected battery cells. The term “level” refers to a count, or ordinal number, of the battery cell groups in the main string. The level thus also refers to the count, or ordinal number, of the battery cell groups in the main string. What is shown in FIG. 2 can be done to reach a higher Ah rating of the module or the battery pack or to reach a higher operating current or power. In the figure, three parallel connected battery cells are shown on each level, but the number can be any number larger than 1. In this figure, also each of the transistors Q1 and Q2 consists of several parallel connected controllable switches, such as MOSFETs, to be able to handle the higher current. Also, the number of controllable switches in parallel can be understood to be any number larger than 1 or one as shown in FIG. 1. All the switches in parallel, in the first switch Q1 and in the second switch Q2, will normally be controlled by a common control signal, a first control signal K1 controlling the switch Q1 and a second control signal K2, controlling the second switch Q2. In case of using parallel MOSFETs as a controllable switch, the gate connections are normally connected to each other, often with a small current sharing resistor between the gates. Also, the source connections are connected to each other, and the drain connections of the transistors are connected to each other.

The circuit according to FIG. 2 has some additional problems in terms of failure modes. In case one of the battery cells in the battery module fails into a short circuit, all cells that are directly parallel connected to the cell that failed, will dissipate their energy into the failed cell, resulting in a higher initial energy release with increased risk for fire. This can be a limiting factor of how many cells can be connected in parallel.

Also, for the transistors, there may be some additional problems. As there are now a greater number of transistors—as compared to in FIG. 1, the probability that a transistor fails into a short circuit is higher. If one of the transistors that embodies the first switch Q1 or the second switch Q2 fails into a short circuit, the total battery pack normally becomes inoperable, such as non-functioning or at least severely limited operable. In case one transistor fails into a short circuit, normally also the gate to source connection will be shorted, which means that also the parallel connected transistor will be impossible to control.

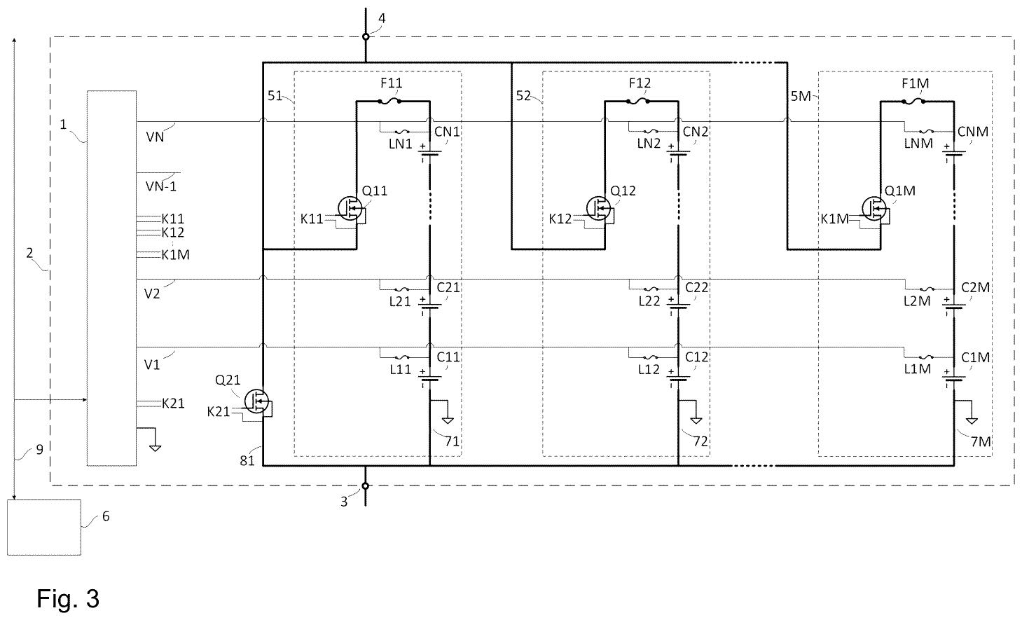

It may here be noted that each of FIG. 3 to FIG. 8 may illustrate one or more examples, since some of the illustrated features are optional and as such these may be omitted in one or more embodiments.

FIG. 3 shows exemplifying battery modules 2 according to some embodiments of the invention.

Only one battery module 2 is shown in this figure for simplicity, but normally several such battery modules are series connected to each other to form a battery pack, in this case a so called re-configurable battery pack. Accordingly, the battery module 2 may be configured for being series connected included in the battery pack. This means for example that the battery module 2 may be controlled by a battery pack controller. In more detail, each of the different battery modules 2 of the battery pack, includes a control circuit 1, where each of the control circuits 1 are connected to a common control unit 6, such as a battery pack controller, a BMS or the like, through a bidirectional control line or control bus 9.

The exemplifying battery module 2 comprises a control circuit, 1 and two or more parallel connected first branches 71-7M, where each of the first branches 71-7M comprises a string of series-connected battery cells C11-C1N, C21-C2N, . . . , CN1-CNM, a first branch over-current protecting component F11, F12, . . . F1M and at least a first switch Q11-Q1M. Typically, the number of first branches is in the range of 2-20, preferably 3-10. The actual number is dependent on the Ah rating and the power rating of each cell and the corresponding design rating of the total battery pack. Throughout the present disclosure, M refers to a branch count indicating number of first branches 71-7M and N refers to a first count of the string of series-connected battery cells, aka “respective plurality of battery cells”.

Expressed somewhat differently, the battery module 2 comprises the control circuit 1 configured to monitor battery cells C11-CNM of the battery module 2 and to control switches Q11-Q1M, Q21-Q2M of the battery module 2, a first node 3 and a second node 4 for charging and/or discharging of the battery module 2, and at least two first branches 71-7M that are parallelly connected between the first and second nodes 3, 4.

Furthermore, each first branch 71-7M of said at least two first branches 71-7M is arranged to be capable of connecting the first and second nodes 3,4 by means of a respective first switch Q11-Q1M of the switches Q11-Q1M, Q21-Q2M. The respective first switch Q11-Q1M may typically be controllable, i.e., the respective first switch may be referred to as the respective first controllable switch. A reason for this is that the respective first switch may be set to open or closed state by the control circuit 1. Said each first branch 71-7M comprises:
a respective plurality of battery cells C11-CN1, . . . , C1M-CNM of the battery cells C11-CNM,
a respective first branch over-current protecting component F11-F1M, and
the respective first switch Q11-Q1M.

In this manner, the first and second nodes 3,4 are connectable to each other via at least the respective first branch over-current protecting component F11-F1M and the respective plurality of battery cells C11-CN1, . . . , C1M-CNM. It may here also be noted that each respective first branch 71-7M may be said to be comprised in a set of first branches 71-7M, i.e., the set of first branches 71-7M comprises each respective first branch 71-7M.

The respective plurality of cells C11-CN1, . . . , C1M-CNM, the respective first branch over-current protecting component F11-F1M and the respective first switch Q11-Q1M are connected in series. This means for example that all of the respective cells of the respective plurality of cells C11-CN1, . . . , C1M-CNM, the respective first branch over-current protecting component F11-F1M and the respective first switch Q11-Q1M are connected in series in any suitable order.

Additionally, the battery module 2 comprises one or more second branches 81-8M arranged to be capable of connecting the first and second node 3,4, i.e., to each other, by means of one or more second switches Q21-Q2M of the number of switches Q11-Q1M, Q21-Q2M. In FIG. 3, only one second branch 81 is shown. Each second branch 81-8M of said one or more second branches 81-8M comprises a respective second switch Q21-Q2M of said one or more second switches Q21-Q2M. According to the example of FIG. 3, this means that said only one second branch 81 comprises a second switch Q21. The second switch Q21 may be embodied by one or more parallel switches as described below. The respective second switch Q21-Q2M may typically be controllable, i.e., the respective second switch may be referred to as the respective second controllable switch. A reason for this is that the respective second switch may be set to open or closed state by the control circuit 1.

Typically, when one or more of said one or more second switches Q21-Q2M is closed all of the respective plurality of battery cells C11-CN1, . . . , C1M-CNM are bypassed.

Moreover, the control circuit 1 is provided with a number of connection lines V1-VN corresponding to at least the first count of the respective plurality of battery cells C1-CN. Each connection line V1-VN of the number of connection lines V0-VN is arranged to parallelly connect a respective set C11-C1M, . . . , CN1-CNM of corresponding battery cells C11-CNM via a respective cell over-current protecting component L11-L1M, L21-L2M, . . . , LN1-LNM for each corresponding battery cell C11-CNM of the respective set of corresponding battery cells C11-C1M, C21-C2M, . . . , CN1-CNM. Said each corresponding battery cell C11-CNM is comprised in a respective first branch 71-7M of said at least two first branches 71-7M.

Throughout the following description, cell circuit arrangements 51-5M are merely intended to provide an alternative or additional way or describing some embodiments herein. The cell circuit arrangements may thus be omitted in some embodiments.

In more detail, the control circuit 1 is thus sensing the average cell voltage of each of the parallel connected cells C11-C1M, C21-C2M, . . . CN1-CNM in the respective first branch 71-7M, using the number of connection lines, V1-VN, connected to the control circuit 1. In this example, the battery cells on the same level, are not directly parallel connected. They are instead connected to the same connection line V1-VN via the cell over-current protecting component L11-L1M, L21-L2M, . . . , LN1-LNM. Each cell over-current protecting component L11-L1M, L21-L2M, . . . , LN1-LNM is typically connected between an anode of said each corresponding battery cell C11-CNM and said each connection line V1-VN that connects to the control circuit 2 and other corresponding battery cells via their respective cell over-current protecting components. As an example, the respective cell over-current protecting component L11-L1M, L21-L2M, . . . , LN1-LNM may be embodied by one or more of a fuse, a resettable fuse, a fusible wire, a fusible resistor, a current limiter, a resistor with positive temperature coefficient, a current limiting diode, and a resistor or the like. In case a fuse or a resettable fuse is used, the rating of the fuse can typically be between 1-10A, but also higher or lower values can be used depending on the size and internal resistance of the battery cells. In case a current limiter or a resettable fuse is used, the current limiting value or tripping point to a high impedance state, can also be in this range.

As shown in FIG. 3, the corresponding cells of the respective set C11-C1M, C21-C2M, . . . , CN1-CNM of corresponding battery cells C11-CNM are corresponding to each other in that a respective second count of cells towards the first and/or second node 3, 4 from said each corresponding battery cell in the respective first branch 71-7M is equal, e.g., to each other.

As an example, for a first particular corresponding cell in a first particular first branch, a first particular second count indicates number of cells towards the first or second node, i.e., in the first particular first branch. For a second particular corresponding cell in a second particular first branch, a second particular second count similarly indicates number of cells towards the first or second, i.e., in the second particular first branch. The first and second particular corresponding cells are corresponding, e.g., to each other, when the first and second particular second counts are equal.

As a further example, it may be said that the corresponding cells are corresponding to each other in terms of their position within their respective plurality of cells C11-CN1, . . . , C1M-CNM. Their positions may be given by the count of cells towards the first and/or second node 3, 4 in their respective first branch 71-7M.

As further elaboration on the meaning of corresponding cells, one or more of the following examples may be applied independently of each other.

Thanks to the number of connection lines V1-VN, the cells of the battery module may be arranged, at least in terms of their electrical connections to each other, into a matrix. While it is commonplace to discuss number of rows and number of columns when dealing with matrices, those commonplace notions may in the context of the embodiments herein be replaced by, while referring to e.g., FIG. 3, the first count of the respective plurality of battery cells as “number of rows” and a branch count indicating number of said at least two first branches as “number of columns”. This means that battery cells that are corresponding to each other have the same ordinal number among their respective plurality of battery cells or are—using commonplace notion-on the same row.

In some examples, each parallelly connected corresponding battery cell of the respective set of corresponding battery cells is connected to the control unit 1 via the respective cell over-current protecting component L11-L1M, L21-L2M, . . . , LN1-LNM.

In some examples, the respective set C11-C1M, C21-C2M, . . . , CN1-CNM of corresponding battery cells C11-C1M, C21-C2M, . . . , CN1-CNM is associated with the respective second count of battery cells towards the first or second node 3, 4 from the corresponding battery cells for each of the respective plurality of battery cells C11-CN1, . . . , C1M-CNM. Using the commonplace notion, this means that the respective set of corresponding battery cells comprises battery cells on the same row. Further, there will be one respective set of corresponding battery cells for each row.

In some examples, the respective second count of battery cells towards the first or second node 3, 4 for said each corresponding battery cell C11-CNM applies to all corresponding battery cells within the respective set of corresponding battery cells C11-C1M, C21-C2M, . . . , CN1-CNM.

In some examples, there is thus a plurality of respective sets of corresponding battery cells, wherein corresponding battery cells of each respective set are corresponding to each other in that a count of battery cells towards the first or second node is equal.

In some examples, the respective second count of battery cells towards the first node 3 applies for each of the battery cells of battery module. In this manner, unique identification of the row of the cells is achieved.

In some examples, the respective second count of battery cells towards the second node 4 applies for each of the battery cells of battery module. In this manner, unique identification of the row of the cells is achieved.

The connection lines V1-VN together with the cell over-current protecting components L11-L1M, L21-L2M, . . . , LN1-LNM, enables resistor switched cell balancing, in case there is need for balancing the SOC between the battery cells within any one or more of the respective sets C11-C1M, . . . , CN1-CNM of corresponding battery cells. Such a switched resistor balancing current is typically in the range of 100 mA-400 mA if it is started. The connection lines V1-VN together with the components L11-L1M, L21-L2M, . . . , LN1-LNM, will also help to balance the SOC of all cells with a certain position in the series connection, to allow current to flow between all C1X cells, between all C2X cells etc., where X is a number between 1 and M, one for each cell circuit arrangement 51-5M, in a similar manner as if the cells were directly parallel connected. However, this balancing current is normally not very high, typically just a few mA up to may be a few amperes in more extreme situations, for example in transient situations where the current through the battery pack is changing fast. The balancing current may also increase due to ageing of cells as a result of that different cells may have a larger variation of capacity as compared to when the cells are new. The balancing current also depends on the resistance value of the cell over-current protecting components L11-L1M, L21-L2M, . . . , LN1-LNM, when the cell over-current protecting component is in low impedance state.

The reason for letting the component L11-L1M, L21-L2M, . . . , LN1-LNM. be a cell over-current protecting component such as a e.g., a fuse, will now be explained. In case one of the battery cells C11-C1N, C21-C2N, . . . , CN1-CNM in the series connection in one of the circuit arrangements 51-5M will fail into a short circuit, the current through the cell over-current protecting component will be limited. In case the cell over-current protecting component is a fuse, the fuse connected to the anode of the failing cell will open. Here it is assumed that the rating of the fuse is chosen such that it will open if the voltage of one cell is dropping to a voltage close to zero. Also, the other fuses connected to the anode of all cells with a higher cell number than the failed cell in the same circuit arrangement will open, as approximately the same voltage difference will appear across all these fuses.

In some examples, said at least two first branches 71-7M comprise at least three first branches 71-7M. As long as the number of first branches 71-7M in the battery module 2 is three or more, the cell over-current protecting components L11-L1M, L21-L2M, . . . , LN1-LNM in the first branches 71-7M with no failed cell will not pass the limiting or tripping value, as the current value of the said cell over-current protecting components will be half or less than half (i.e. 1/n, where n is the number of remaining first branches with no failed corresponding cell, where n>=3) of the current passing the cell over-current protecting components in the first branch with the failed cell, such as short circuit. In case there is only two first branches one of the components will limit the current or open, but it cannot be ensured that it is the one which is connected to the anode of the failed cell. This means that the energy release in the failed cell will be limited to the energy of its own cell plus some small energy that is supplied from the cells in the other circuit arrangements before the fuses opens.

In case some other type of cell over-current protecting component is used, such as e. g a resettable fuse the power will not drop to zero but to a small value. Using a fuse or a resettable fuse, the energy supplied from the other cells into the failing cells will be small and can normally be neglected as compared to the energy in the failing cell. In case of using other type of cell over-current protecting components, the power delivered from the other battery cells into the failing cell will be limited.

Also, one of the first branch over-current protecting components F11-F1M will be used to limit the energy dissipation into the failed cell. If all first switches Q11-Q1M is on and all second switches Q21-Q2M are off, at the time when one battery cell is shorted, the first branch over-current protecting component F11-F1M in the first branch 71-7M of the shorted cell, will also open, at least in in examples in which there are three or more first branches 71-7M. In case of only two first branches 71-7M, one of the first branch over-current protecting components F11-F1M will open to limit the energy dissipation into the failed cell, but it is here uncertain which one of the first branch over-current protecting components that will open. Here it is again assumed that the rating of the first branch over-current protecting component F11-F1M is chosen such that it will open if the voltage of one cell is dropping to a voltage close to zero. The current rating for this first branch over-current protecting component, must be higher than the maximum current that will pass the string of cells in normal case. A suitable rating might be 10A-200A, and the rating of this first branch over-current protecting component is dependent of the maximum current that the cells are designed for. At the time for failure, the other first branches will start to deliver a high current to all the battery cells in the first branch with the failing cell, which will result in that the first branch over-current protecting component in the first branch with the failed battery cell will open. Also in this case, the energy fed from the other cells to the first branch with the failing cell, will be very limited, as the first branch over-current protecting component F11-F1M will be designed to open quickly.

This means, that the energy release into the failing cell can be limited which is an advantage. If the battery module is designed to handle the energy of one cell failing into short circuit, without thermal runaway of adjacent cells, the invention can be used to prevent fire due to a single cell short circuit event.

The first branch with the failing cell will also be disconnected from the battery module. This means, at least if the battery module is designed to handle a single cell short circuit event, that the other first branches of battery module can continue to operate.

The battery module can also handle single failure of one cell going to open circuit, one of the transistors Q11-Q1M, Q21-Q2M failing into short circuit or one of transistors Q11-Q1M, Q21-Q2M failing into open state (not controllable anymore) with the internal diode still working.

In case one of the transistors Q11-Q1M fails into a short circuit, and the opposite transistor Q21-Q2M is turned on or already is in the closed state, the first branch over-current protecting component F11-F1M in the circuit arrangement with the failing transistor will open. This will limit the energy dissipated into the transistor, reduce the risk for physical damage of the circuit board where the transistor is mounted and also reduce the risk for arcing or fire.

This means that one circuit arrangement is disconnected from the battery module and the battery module can still operate. The control circuit can be equipped with means for detecting that one transistor has failed, for example by sensing the impedance in the control wire to the failed transistor.

In some embodiments, the control circuit 1 in each battery module 2 is controlling all of the first switches Q11-Q1M through the control signals K11-K1M and the second switches Q21-Q2M, through the control signals K21-K2M (only one second switch is shown in FIG. 3). As an example, the control circuit 1 may be provided with a first control node (not shown), such as a wire, connection line, conducting line or the like, for all of the first switches Q11-Q1M. Similarly, the control unit 1 may be provided with a second control node (not shown) for all of the second switches Q21-Q2M.

Alternatively or additionally, the control circuit 1 may control all first switches Q11-Q1M independently from each other and all the second switches Q21-Q2M independently from each other (in case there is more than one branch 81 with more than one second switch Q21-Q2M). In this case, the control circuit 1 is arranged to send a respective control signal K11-KNM to each one of the first switches Q11-QNM. By independent control, it is for example possible to turn on only one of the first switches Q11-Q1M while having all other switches Q11-Q1M, Q21-Q2M in open state. As an example, the control circuit 1 may be provided with a respective control node (not shown), such as a wire, connection line, conducting line or the like, for each one of the first switches Q11-Q1M and the second switches Q21-Q2M.

This makes it possible to select one or several string of cells inside a battery module 2 to be included in the battery pack or not.

In case the second switch Q21 in FIG. 3 will fail into a short circuit and one or several of the switches Q11-Q1M is turned on or already is in closed state, the first branch over-current protecting components F11-F1M will protect the cells from being shorted for any longer time and reduce the risk for arcing or fire. In this case it is not recommended to operate the battery module or the battery pack for any longer time after such a failure. It is preferred that the control circuit 1 have means for detecting such a failure.

It can also be shown that the circuit according to the invention can handle other failure modes such as open circuit of a cell or open circuit of a transistor switch and that the battery pack and part of the battery module can still operate after such a failure, even with some derating.

To detect all these different fault cases, suitable sensors can be added to the circuit arrangement in FIG. 3 to make it possible for the control circuit 1 to detect these cases, such as sensing the current in a branch 71-7M and/or 81-8M or the sum of current in a branch 71-81, . . . 7M-8M, or the voltage of across one first branch over-current protecting component F11-F1M as a few examples. There are also numerous other ways to detect the different fault cases, but these methods are not explicitly mentioned here.

It can be summarized that at least some embodiments of the invention provide beneficial advantages as compared to the conventional circuits according to FIG. 1 and FIG. 2, with reduced energy transfer to a failed battery cell or energy transfer to a transistor failing into a short circuit.

It may here be noted that embodiments of the invention may also be used in configurations that includes an H-bridge in the context mentioned in the background section.

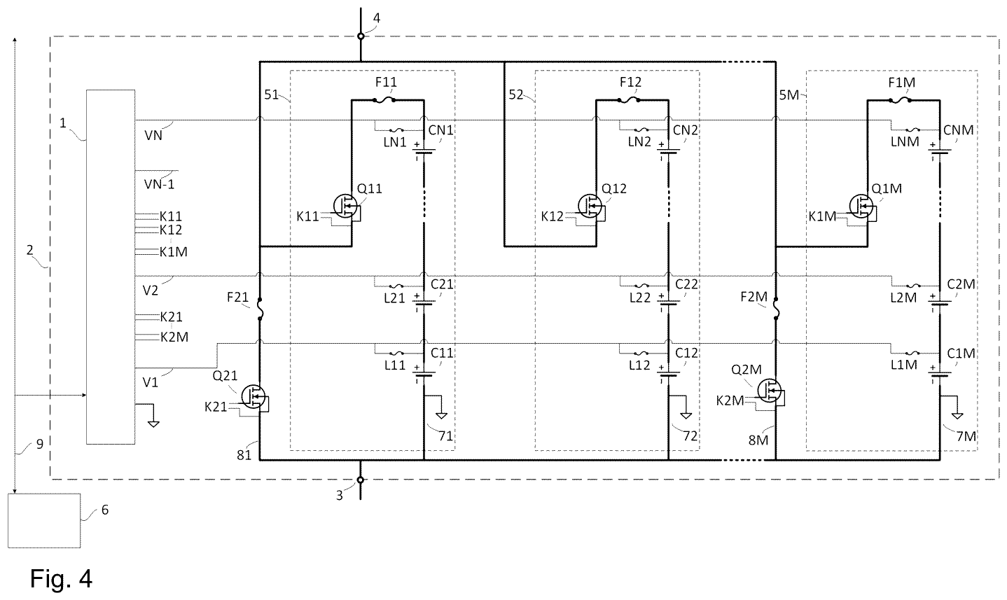

FIG. 4 shows another exemplifying battery module, in which said one or more second branches 81-8M comprise at least two respective second branches 81-8M. Said at least two respective second branches 81-8M comprise a respective second branch over-current protecting component F21-F2M connected in series with the respective second switch Q21-Q2M of said at least two second branches 81-8M. Accordingly, in this example, the respective second branch over-current protecting component F21, F22, . . . . F2M has been added to the battery module 2 with said at least two respective second branches 81-8M, in series with the respective second switch Q21-Q2M. The respective second branch over-current protecting component F21, F22, . . . F2M and the respective second switch Q21-Q2M can change order as long as they are series connected in the same branch 81-8M. This case gives some additional benefits in terms of the possibility operate the battery module after a single failure of the second switch Q21-Q2M into a short circuit. In this case it is possible to turn-on all the switches Q11-Q1M, which will result in that one of the second branch over-current protecting components F21-F2M in the branch of the failing transistor will open, resulting in that it will still be possible to use all cells in the module. The only thing which happens is that the number of parallel transistors Q21-Q2M that will share the total battery pack current in bypass mode, will be one less than before.

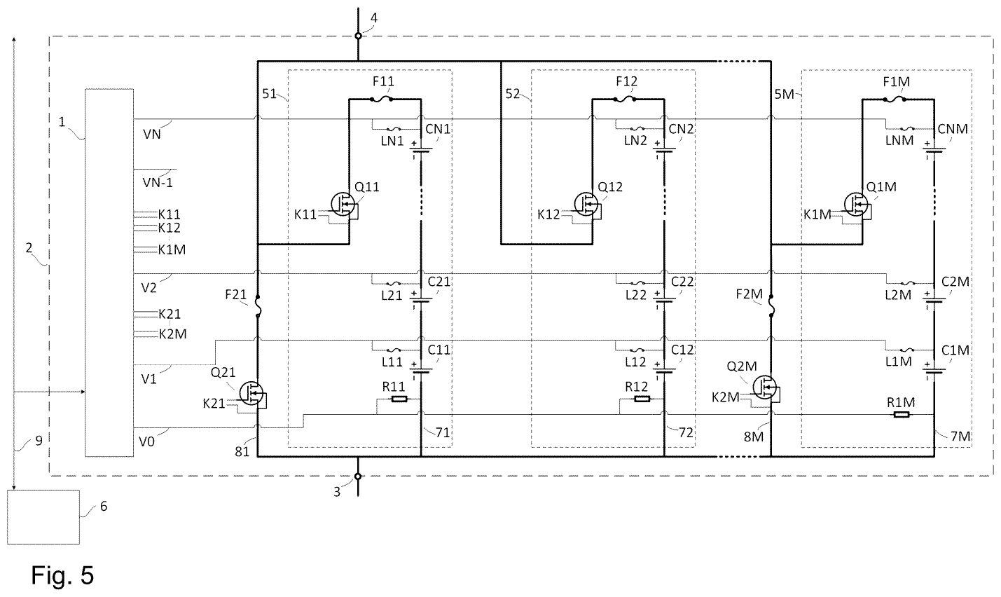

FIG. 5 shows a further exemplifying battery module, in which the control circuit 1 is provided with a further connection line V0 that is connected to each first cell of the respective plurality of cells C11-CN1, . . . , C1M-CNM, e.g., via a respective resistor R1-RM. This resistor is not absolute necessary and can have a value of zero ohm or close to zero ohm, but it can be a benefit to have a small resistance here, depending on the physical layout of the battery module, to reduce the current through the branches where the respective resistors R11-RIM are inserted. Said each first cell is closest to the first node 3 among the cells of the respective plurality of battery cells C11-CN1, . . . , C1M-CNM. In this manner, the ground node next to e.g., the battery cell C11 in FIG. 3 may be dispensed with. Thanks to the further connection line V0, the control circuit 1 may still measure the voltages over each battery cell.

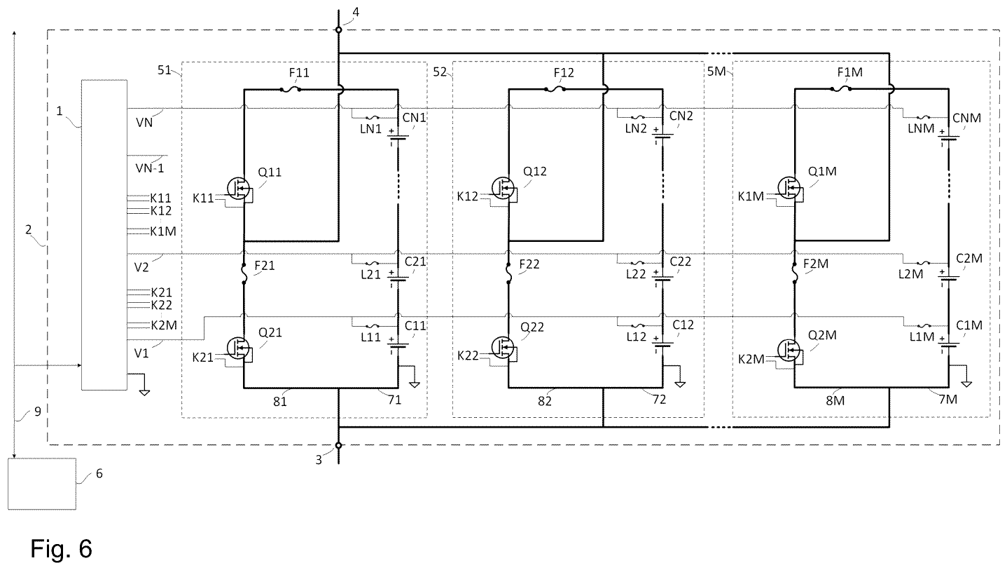

FIG. 6 shows a further exemplifying battery module 2. This example is similar to the example of FIG. 4. Notably, there is in FIG. 6 a respective second branch 81-8M for each first branch 71-7M. Optionally, the respective second branch 81-8M comprises a respective second branch over-current protecting component F21-F2M.

In view of the exemplifying battery modules above, it may be noted that even though these examples are fully functional and provides considerable advantages, further improvement may be achieved as explained in the following.

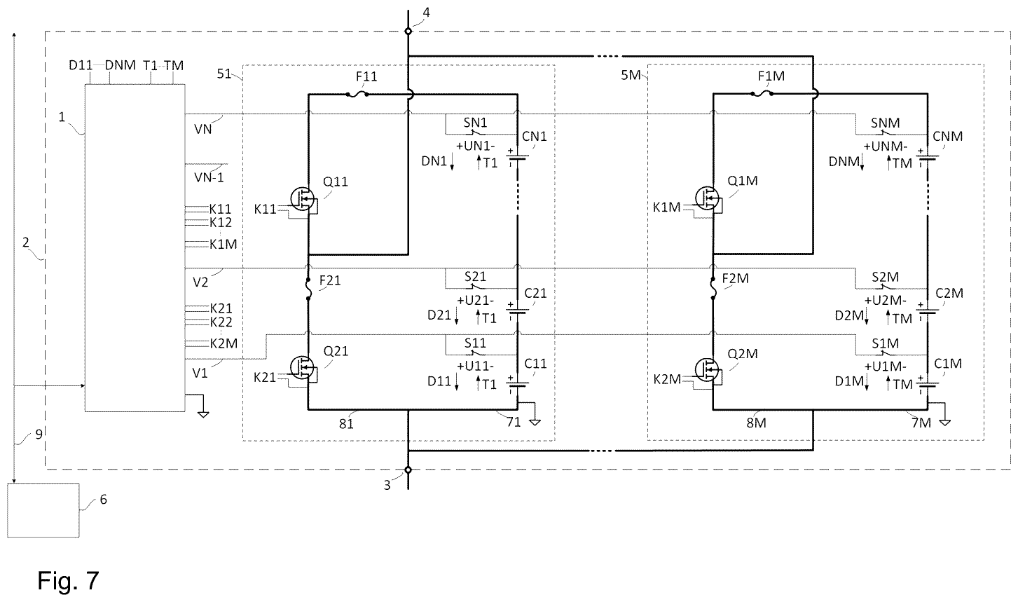

Considering, for example, the example of FIG. 6, measurements of voltages of the cells will be achieved as an average voltage of those cells connected to the same respective connection line V1-VN, i.e., on the same level. With the example of FIG. 7 below a more accurate measurement of the voltage over each battery cell may be achieved. It shall here also be noted that all of the examples and embodiments as described above may, when suitable, be applied to the examples of FIG. 7 and the related aspect.

FIG. 7 shows a further exemplifying battery module 2. The figure is similar to the example of FIG. 6. In FIG. 7 only two cell circuit arrangements 51, . . . 5M are shown, but the number of cell circuit arrangements can be two, three or more as explained above with related benefits and advantages. Again, the cell circuit arrangements 51-5M are merely intended to provide an alternative or additional way or describing some embodiments herein. Also, the second branch over-current protecting component F21-F2M, shown in FIG. 7, is optional, but if it is included it will give advantages as already discussed in the example of FIG. 4. The number of branches 81-8M including the switch Q21-Q2M in the battery module 2 does not need to be same as the number of cell circuit arrangements 51-5M as already discussed in the examples in FIG. 4 and FIG. 6.

The battery module 2, shown in FIG. 7, comprises a control circuit 1 configured to monitor battery cells C11-CNM of the battery module 2 and to control switches Q11-Q1M, Q21-Q2M of the battery module 2.

As mentioned according to other examples, the battery module 2 comprises a first node 3 and a second node 4 for charging and/or discharging of the battery module 2.

Moreover, the battery module 2 comprises at least two first branches 71-7M that are parallelly connected between the first and second nodes 3, 4.

Each first branch 71-7M of said at least two first branches 71-7M is arranged to be capable of connecting the first and second nodes 3,4 by means of a respective first switch Q11-Q1M of the switches Q11-Q1M, Q21-Q2M.

Said each first branch 71-7M comprises a respective plurality of battery cells C11-CN1, . . . , C1M-CNM of the battery cells C11-CNM, and the respective first switch Q11-Q1M. Again, the respective plurality of cells C11-CN1, . . . , C1M-CNM and the respective first switch Q11-Q1M are connected in series.

In some embodiments, said each first branch 71-7M further comprises a respective first branch over-current protecting component F11-F1M. In FIG. 7, the respective first branch over-current protecting component F11-F1M is shown but is of course optional.

Furthermore, the battery module 2 comprises one or more second branches 81-8M arranged to be capable of connecting the first and second nodes 3,4 by means of one or more second switches Q21-Q2M of the switches Q11-Q1M, Q21-Q2M, wherein each second branch 81-8M of said one or more second branches 81-8M comprises a respective second switch Q21-Q2M of said one or more second switches Q21-Q2M.

The control circuit 1 is provided with a number of connection lines V1-VN corresponding to at least a first count of the respective plurality of battery cells C11-C1M.

Each connection line V1-VN of the number of connection lines V1-VN is arranged to parallelly connect a respective set C11-C1M, C21-C2M, . . . , CN1-CNM of corresponding battery cells C11-CNM to each other via a respective controllable over-current protecting component S11-S1M, . . . , SN1-SNM for each corresponding battery cell C11-CNM of the respective set of corresponding battery cells C11-C1M, C21-C2M, . . . , CN1-CNM. As an example, the respective controllable over-current protecting component S11-S1M, . . . , SN1-SNM is controlled by the control circuit 1. Thus, the control circuit 1 is configured to set the respective controllable over-current protecting component S11-S1M, . . . , SN1-SNM to an open or closed state. In one example, the respective controllable over-current protecting component S11-S1M, . . . , SN1-SNM is a self-protected electronic switch or the like disclosed herein. Said each corresponding battery cell C11-CNM is comprised in a respective first branch 71-7M of said at least two first branches 71-7M.

The corresponding battery cells of the respective set C11-C1M, C21-C2M, . . . , CN1-CNM of corresponding battery cells C11-CNM are corresponding to each other in that of a respective second count of battery cells towards the first and/or second node 3, 4 from said each corresponding battery cell in the respective first branch 71-7M is equal.

The same or similar examples and description concerning the corresponding battery cells as for other embodiments herein applies.

In some embodiments, the control circuit 1 is configured to send a respective control signal T1-TM to a corresponding set of respective controllable over-current protecting components S11-S1M, . . . , SN1-SNM. The corresponding set of respective controllable over-current protecting components S11-S1M, . . . , SN1-SNM corresponds to said each first branch 71-7M in that the corresponding set of respective controllable over-current protecting components S11-S1M, . . . , SN1-SNM comprises those respective controllable over-current protecting components S11-S1M, SN1-SNM for which said each corresponding battery cell C11-CNM is included in said each first branch 71-7M. This means that for a particular first branch, the control circuit 1 may send a particular respective control signal to all controllable switches in the particular first branch.

In view of the above, a difference between some of the examples in FIG. 7 and the example in FIG. 6, is for example that the cell over-current protecting component L11-LN1, . . . L1M-LNM has been replaced by a controllable over-current protecting component S11-SN1, . . . S1M-SNM that optionally may be controlled from the control unit 1 with the respective control signal T1, . . . TM. Normally it is enough to use one common control signal T1, —TM for each cell circuit arrangement 51-5M, meaning that all the controllable over-current protecting components S11-SN1 in one cell circuit arrangement can be controlled with one common control signal T1 etc. It is however also possible to use individual control signals from the control unit 1 to each of the controllable over-current protecting components S11-SN1, . . . S1M-SNM.

The controllable over-current protecting component S11-SN1, . . . S1M-SNM, such as a controllable switch, will normally be closed, meaning that the current can pass the switch at low resistance, such as e.g., a resistance of typical 1-10 mohm. This means that the all the battery cells on the same level can exchange charge with each other.

In some embodiments, the respective controllable over-current protecting component S11-S1M, . . . , SN1-SNM is configured to autonomously enter a latched state, in which the respective controllable over-current protecting component S11-S1M, . . . , SN1-SNM is in an open state, when a threshold value relating to current through the respective controllable over-current protecting component S11-S1M, . . . , SN1-SNM and/or relating to voltage over the respective controllable over-current protecting component S11-S1M, . . . , SN1-SNM is exceeded or reached. In the open state of the controllable switch current presents a high impedance, such that no or almost no current can pass through the controllable switch. In this context, “autonomously” refers to that the controllable switch enters the latched state without being controlled by e.g., the control circuit 1. Instead, the controllable switch may be said to include a local sub-control circuit (not shown) that ensures that the latched state is entered when the threshold value is reached or exceeded. However, the respective controllable over-current protecting component may only re-enter the closed state upon receiving a control signal, from e.g., the control circuit 1 as explained below.

In more detail, each of the controllable over-current protecting components S11-SN1, . . . S1M-SNM are equipped with a sensor, such as a sensor sensing the current passing the controllable over-current protecting component and the direction of the current, or the voltage U11-UN1, . . . U1M-UNM across the controllable over-current protecting component. If this sensed current or sensed voltage is passing the threshold value with a current direction/voltage direction such that the associated battery cell C11-CN1, . . . C1M-CNM, will be charged by this current, the controllable over-current protecting component will be turned off into the latched state, to stop the current from flowing or only allowing a very small amount of current to restrict the current flow into the battery cell. Such a controllable over-current protecting component may behave essentially as a fuse as described earlier. The controllable over-current protecting component can for example be a controllable switch, a transistor such as a P-channel or N-channel MOSFET, which only needs to be capable of turning off a relatively low voltage, such as 4-5V, corresponding to one cell voltage, and typically such a switch can have a voltage rating of 6-25V.

The triggering action to a latched state, can be done for example by a comparator, sensing the voltage across the controllable over-current protecting component or the current passing the controllable over-current protecting component through a small current measurement resistor or the like. If this measured current or voltage is passing the threshold value, the controllable over-current protecting component will autonomously be turned off. The typical case that will cause this trigger action is if one of the respective cells C11-CN1, . . . C1M-CNM has failed into a short circuit condition as explained earlier. This means for example that the local sub-control circuit may include one or more of the components mentioned above that are required to achieve the desired function of autonomously entering the latched state when the threshold value is exceeded or reached.

Other possible cases, where one or several of the controllable over-current protecting component S11-SN1, . . . S1M-SNM can open due to over-current, is in case of a shorted transistor Q1X in one branch 7X. In this case the current pulse time will be limited by the first branch over-current protecting component FIX that will open after a certain time. In such a case, it can be advantageous to turn-on the controllable over-current protecting components S1X-SNX that has opened and latched to be in open state. These controllable over-current protecting components may thus have released, e.g., opened, before the first branch over-current protecting component FIX opened. The turning-on of the controllable over-current protecting components can for example be done by toggling the control signal TX and to have a logic circuit that makes the controllable over-current protecting components S1X-SNX to reset from the latched state to on-state again, such as the closed state of the controllable over-current protecting component, in case the signal TX is toggled. In this manner, the battery cells, in the otherwise completely unusable first branch 7X, may leak current to battery cells in the other first branches via the respective controllable over-current protecting component on the respective connection line.

Therefore, according to some embodiments, the control circuit 1 is configured to send a reset signal to the respective controllable over-current protecting component S11-SIM, . . . , SN1-SNM, wherein the reset signal instructs the respective controllable over-current protecting component S11-S1M, . . . , SN1-SNM to be set in a closed state. In the closed state, the controllable over-current protecting component may present a low impedance and/or be in the closed state. As explained above, the reset signal may be embodied by toggling the respective control signal T1-TM.

It can be concluded that these examples show that the controllable over-current protecting component, referred to as “switch” for short, may behave as a fuse that goes into a high impedance state if the current passing the switch is high enough, i.e., over the threshold value. There is however one difference. The switch does not need to be tripped to a high impedance state if the current direction is opposite, such that the cell associated with one switch is discharged through the switch. In this case the switch does not need to be tripped. This may be advantageous as it may ensure that the controllable switch associated with a failed cell or in the same cell circuit arrangements 51- . . . 5M as one failed cell will be tripped and not the controllable over-current protecting components in the other first branches associated with cells that are discharged and feed energy into the failed cell.

Tripping means that a threshold value of the over-current protecting component is exceeded, or reached, and the over-current protecting component then autonomously enters the open state, in which the component may or may not be latched.

An advantage with at least some of the examples of FIG. 7 will now be explained. The control unit is now equipped with a control signal T1, . . . TM, that can turn on or turn off all the controllable switches in one of the respective first branches 71-7M. This makes it possible for the control unit to measure all cell voltages C11-CN1, . . . C1M-CNM, individually, through the connection lines V1-VN. This can be done when no current is passing the respective string of cells C11-CN1, . . . C1M-CNM and at low enough battery pack current, which will be explained in more detail below.

It is in the following assumed that the control unit 6 is equipped with at least one current sensor to sense the battery pack current, flowing through series connected battery modules 2. It is also assumed that the control circuit 1, at low battery pack current, can command all first branches 71-7M except one to be disabled. This means that one of the first switches Q1X is turned on for one particular first branch 7X and that all other switches Q11, Q21, . . . Q1M, Q2M will be turned off.

Accordingly, in some embodiments, the control circuit 1 is configured to receive a number of indications relating to voltage over each battery cell C11-CN1, . . . , C1M-CNM in a particular first branch 71-7M by being configured to set the respective controllable over-current protecting component S11-S1M, SN1-SNM in said particular first branch 71-7M to allow current through the respective controllable over-current protecting component S11-S1M, . . . , SN1-SNM, and to set the respective controllable over-current protecting component S11-S1M, . . . , SN1-SNM in other first branches 71-7M but said particular first branch 71-7M to open whereby current through the respective controllable over-current protecting component S11-S1M, . . . , SN1-SNM is stopped.

The number of indications may be received using the connection lines and/or the number of indications may be embodied by diagnose signals as described below.

In this manner, the battery pack current flowing through the battery module will be directed to pass only the respective plurality of battery cells in the particular first branch 7X with the respective first switch Q1X turned on. This may preferably be performed at a time when the battery pack current is low enough, meaning that one string of cells is capable of handling the total battery pack current. If this is done during charging, the current needs to be low enough, to ensure that the battery pack current is only passing the string of cells with the respective first switch Q1X closed. At higher currents, the current will start to flow also into string of cells with the switch Q11-Q1M opened, through the reverse diode in the switch Q11-Q1M that is turned off.

If the battery pack current is higher, the individual cell voltages C11-CN1, . . . . C1M-CNM can be measured at a time when the total battery module is controlled by the control unit 6 to be in bypass state, meaning that all the first switches Q11-Q1M are off and all the second switches Q21-Q2M are on.

In case the battery pack current zero, the individual cell voltages can also be measured, independently of the state of the different switches Q11-Q1M, Q21-Q2M.

Now to measure the individual cell voltages, the control circuit 1, possibly instructed by the control unit 6, will set the control signals T1-TM such that all the controllable over-current protecting components S11-SN1, . . . S1M-SNM will be opened except for one particular first branch 7X, where all the controllable over-current protecting components S1X-SNX will be turned on by commanding this through the control signal TX. As the control circuit 1 may have a high input impedance to measure the cell voltages, the current through the controllable over-current protecting components S1X-SNX that is in on-state, will be close to zero, meaning that the voltage V1X-VNX will be very close to zero and the connection lines V1-VN can be used to measure the individual cell voltages of the cells C1X-C1N. As mentioned above, the number of indications may be received using the connection lines. By letting X go from 1 to M, all the individual cell voltages can be measured in a sequence. Such a sequence can be applied when the battery module 2 is controlled by the control unit 6 to be in bypass state or at low enough battery pack current as explained earlier.

This means that, according to some embodiments, the control circuit 1 is configured to repeat the setting of the respective controllable over-current protecting component S11-S1M, . . . , SN1-SNM in said particular first branch 71-7M and the setting of the respective controllable over-current protecting component S11-S1M, . . . , SN1-SNM in other first branches 71-7M but said particular first branch 71-7M for said each first branch 71-7M, e.g. comprising said particular first branch 71-7M.

With this possibility to be able to measure the open circuit voltage as well as the voltage at a low current across all the individual cells in the battery module, the estimation of SOC and also internal resistance of each cell can be improved and extended to all cells. This information may reduce the risk for that any individual cell will be overcharged or undercharged. On a system level this may be used to reduce the risk for overstressing cells, longer battery pack lifetime, improved charging time, increased knowledge of the available power etc. for the battery pack.

FIG. 7 shown an optional diagnose signal D11-DN1, . . . D1M-DNM for each controllable over-current protecting component S11-SN1, . . . S1M-SNM. The diagnose signal is optionally delivered to the control circuit 1. The diagnose signal may be indicating the state of the respective controllable over-current protecting component S11-SN1, . . . S1M-SNM, which can be advantageous for the control circuit 1 to be aware of. Other information of interest which may be useful as diagnose may be the voltage across each of the controllable over-current protecting components S11-SN1, . . . S1M-SNM, that optionally can be passed to the control circuit 1, either as an analog value, or as for example a digital or digital coded-signal, indicating that the voltage is over a certain threshold value or a certain number of threshold values, such as warning, error etc., to indicate that one cell is either charged from other cells or discharged at a higher rate than what is normal. Such information can be useful, for example at high charging currents, to find cells that has started to age, with risk for overcharging etc. Such information may for example be used to adapt the charging rate or the State Of Power (SoP) at discharging to lower values, due to ageing of cells etc. Such information may also be used to bypass a module more often in case one of cells in the module starts to behave different from the others. Using the diagnose signal as an indicator of the voltage across each controllable over-current protecting component, enables a control circuit 1 or a common control unit 6 to analyze how much the individual cells differs from each other also at higher battery currents. This may improve the measurement of the series resistance of each individual cell during charging and discharging. As it may not be necessary to know this information for every cell in every detail, it may be enough to only have a warning in one or several levels.

As previously discussed, the respective controllable over-current protecting components S11-S1N, S1M-SNM is assumed to be equipped with sensors and a comparator that makes the controllable over-current protecting component to be tripped to a latched high impedance state in case the charging current towards an associated cell through the controllable over-current protecting component is higher than a certain value, such as a threshold value. However, in case the diagnose signal D11-DN1, . . . D1M-DNM contains this information of when the current is passing a certain threshold or in terms of an analog value of voltage across the controllable over-current protecting component or current through the switch, it may be possible to make the tripping decision inside the control unit 1 instead of as a part of the controllable over-current protecting component itself with a preset tripping threshold.

It can further be noted that the implementation of the controllable over-current protecting component, including sensors, comparators, diagnostics etc. may preferably be integrated into one or several integrated circuits, to reduce costs and to improve reliability. With integrated circuit technology several such controllable over-current protecting components with peripheral units can be integrated into one IC (integrate circuit) circuit, either to include the controllable over-current protecting components needed for one string of cells, which may be preferable or to include the controllable over-current protecting components for one row of cells with a certain position in the respective cell circuit arrangements.

In the FIG. 7, the respective control signals T1-TM, is indicated as one common control signal TX controlling all the controllable over-current protecting components S1X-S1N in one first branch 7X. If the controllable over-current protecting components are implemented as a MOSFET, such as for example a p-channel MOSFET, this common control signal might be connected to a level shifting transistor pair including a few resistors to handle that the MOSFETs are located at different voltage potential versus the local ground point of the battery module. Such level shifters may also be implemented using integrated circuit technology.

For completeness, it is again noted that, according to some of the examples according to FIG. 7, said one or more second branches 81-8M comprise at least two respective second branches 81-8M, wherein said at least two respective second branches 81-8M comprise a respective second branch over-current protecting component F21-F2M connected in series with the respective second switch Q21-Q2M of said at least two second branches 81-8M.

Also, as mentioned, according to some of the examples according to FIG. 7, said at least two first branches 71-7M comprise at least three first branches 71-7M.

In view of the various examples described above, the following exemplifying ratings may apply. Rating may refer to maximum power before failure, such as short circuit or break/open, threshold current, or interrupt current, before failure or the like.

The interrupt current rating of the first branch over-current protecting component F11-F1M is typically higher than the maximum short circuit current that can be delivered from one string of cells at the maximum voltage of each string of cells. Typical values of interrupt current ratings can be in the range of 300A-6000A, depending on the size of the cells and the internal resistance of the cells at a typical maximum voltage of 30-60V for one string or cells. As this invention is primarily intended to be used with small to medium size cells, more typical values of interrupt current ratings might be 500A-2000A.

The max continuous current rating for the first branch over-current protecting component F11-F1M may typically be chosen such that it with margin can handle the maximum continuous current per string of cells. Typical values may be 10A-200A, more typically 20-80A.

The interrupt current rating and continuous rating of the second branch over-current protecting component F21-F2M is dependent on the number of branches 71-7M as compared to the number of branches 81-8M. In case they are equal in number the ratings will be the same, in case the number of branches 71-7M is higher than the number of branches 81-8M, the rating of the second branch over-current protecting component F21-F2M is correspondingly higher than the rating of the first branch over-current protecting component F11-F1M.

For the cell over-current protecting component L11-LNM, the ideal case is that the series resistance of the cell over-current protecting component in normal operation is small and in the same order of magnitude as the internal resistance of a new and not aged cell at normal operating temperature. This means that the balancing current is not hindered very much as compared to a situation where the cells were directly parallel connected. Typical serial resistances may be 0.5-20 mohm for a fresh cell, depending on size of the cells, temperature, SOC, current direction and if it is a cell optimized for very high power with low internal resistance or a cell with high energy content, which normally has a higher series resistance. As long as the resistance of the current limiter normally is in the same order as the internal cell resistance or lower, the balancing current between cells in the same order, or same level, will not be hindered so much resulting in that all the cells on the same level will have similar cell voltage and also similar SOC, also when the cells get older. The fuse rating or the tripping point to a high impedance state shall be selected such that it is considerably lower than the current that will pass the current limiter in case of a shorted cell and typical rated values or tripping points may be 2A-40A, more typical 4-20A. The resistance after tripping, or entering open state when exceeding threshold value, may be so high that the power transferred to the shorted cell and that the power in the power limiter can be handled after tripping. For a resettable fuse this typically means a resistance higher than 10 ohm or higher with a continuous power dissipation after tripping to the higher resistance state may be in the range of 1 W or lower.

In case active electronics is used instead of a fuse as a controllable over-current protecting component S11-SNM, the voltage rating of the switch included in the controllable over-current protecting component is higher than 5V, typically in the range of 6-25V or more typical in the range of 8-20V. The serial resistance of the switch included in the controllable over-current protecting component is similar to what is mentioned for the fuse, such as in the range of 0.5-10 mohm or slightly higher such as 2-10 mohm. It can be noted, by using a controllable switch, it may be possible to use a slightly higher on-state resistance as compared to when using a fuse, as with the controllable switch it is possible to measure the voltage across each cell individually. With a fuse, a very low on-state resistance is needed, to ensure that the individual cell voltages are close to the average value of the cell voltage which is measured by the controller. The tripping point may be 2A-40A or more typical 4-20A. The current passing the switch after tripping is normally low such as 10 mA or lower.

For the first switches Q11-Q1M, the first switch may have a continuous current rating that exceeds the maximum current for each string of cells. The current rating may be 10-200A, more typical 20-80A. The first switch shall also ideally be able to handle the current pulse that will happen in case a cell is shorted, until the current is interrupted by the fuse F11-F1M which may be a current of 25 A-800A, more typically 50A-300A. The first switch may further ideally have a specification that makes it unaffected or does not explode in case the first switch fails to a short circuit, with current pulses in the range of 300A-6000A or more typically 500A-2000A until one of the fuses F11-F1M or the one of the fuses F21-F2M is opened.

The continuous current rating of the second switch Q21-Q2M may be same as the continuous current rating of the first switch Q11-Q1M as long as the number of branches 71-7M is equal to the number of branches 81-8M, in case the number of branches 71-7M is higher than the number of branches 81-8M, the rating of the switches Q21-Q2M is correspondingly higher than the continuous current rating of the switches Q11-QM. The same thing is also valid for the specification for the switch in case of short circuit of the switch, to make it unaffected or not to explode (equal rating or higher rating as for the switch Q11-Q1M, depending on the number of first branches 71-7M as compared to the number of second branches 81-8M).

In some embodiments, the first branch over-current protecting component is preferably one of the following components: a non-controllable first branch over-current protecting component, a fuse, a resettable fuse, a fusible resistor, a fusible wire, a self-protected normally conducting transistor, a smart IC circuit with such mentioned current protecting characteristics, a current circuit breaker with built-in overcurrent protection, more preferably a fuse or a self-protected normally conducting transistor as this may be the most cost effective and reliable implementation of this component with current status of technology.

In some embodiments, the second branch over-current protecting component is preferably one of the following components: a non-controllable second branch over-current protecting component, a fuse, a resettable fuse, a fusible resistor, a fusible wire, a self-protected normally conducting transistor, a smart IC circuit with such mentioned current protecting characteristics, a current circuit breaker with built-in overcurrent protection, more preferably a fuse or a self-protected normally conducting transistor as this may be the most cost effective and reliable implementation of this component with current status of technology.

In some embodiments, the cell over-current protecting component is preferably one of the following components: a non-controllable cell over-current protecting component, a fuse, a resettable fuse, such as a PPTC (polymeric positive temperature coefficient) device, a fusible resistor, a fusible wire, a self-protected normally conducting transistor, a smart IC circuit with such mentioned current protecting characteristics, a current limiting diode, a resistor with a large positive temperature coefficient, more preferably a fuse, a fusible resistor or a self-protected normally conducting transistor as this may be the most cost effective and reliable implementation of this component with current status of technology.

In some embodiments, the controllable over-current protecting component is preferable a self-protected normally conducting transistor or a smart IC circuit with such mentioned current protecting characteristics or the like.

As used herein, the term “self-protected”, “self-protected transistor” or the like, refers to that the component, such as the transistor, comprises an internal control circuit or the like that protects the component from being destroyed by over-currents and the like. As an example, a self-protected electronic switch or self-protected over-current protecting component may be configured to autonomously enter open state based on a threshold value, e.g., for voltage/current/power as described herein.

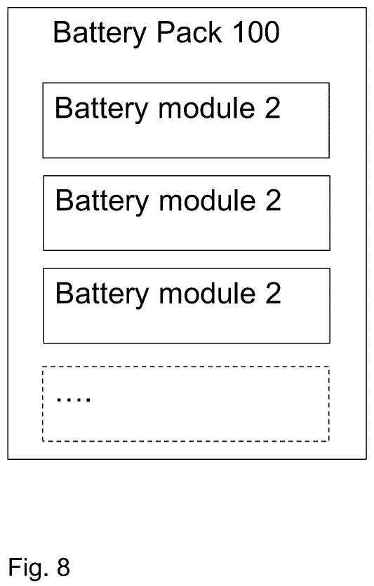

FIG. 8 shows an exemplifying battery pack 100 comprising one or more battery modules 2 according to any one of the examples in FIGS. 3-7 and the embodiments and/or examples disclosed herein. The battery modules 2 are typically series connected with each other. As already mentioned, the battery pack may be a re-configurable battery pack, because the configuration in terms of battery cells that contributes to a desired output voltage and/or output current of the battery pack may be re-configured, e.g., the number of cells may be dynamically changed, e.g., during charging and/or discharging.

Even though embodiments of the various aspects have been described, many different alterations, modifications and the like thereof will become apparent for those skilled in the art. The described embodiments are therefore not intended to limit the scope of the present disclosure.

1. A battery module (2) comprises:
a control circuit (1) configured to monitor battery cells (C11-CNM) of the battery module (2) and to control switches (Q11-Q1M, Q21-Q2M) of the battery module (2),
a first node (3) and a second node (4) for charging and/or discharging of the battery module (2),
at least two first branches (71-7M) that are parallelly connected between the first and second nodes (3, 4),
wherein each first branch (71-7M) of said at least two first branches (71-7M) is arranged to be capable of connecting the first and second nodes (3,4) by means of a respective first switch (Q11-Q1M) of the switches (Q11-Q1M, Q21-Q2M), wherein said each first branch (71-7M) comprises:
a respective plurality of battery cells (C11-CN1, . . . , C1M-CNM) of the battery cells (C11-CNM), and
the respective first switch (Q11-Q1M),
wherein the respective plurality of cells (C11-CN1, . . . , C1M-CNM) and the respective first switch (Q11-Q1M) are connected in series, and
wherein the battery module (2) comprises:
one or more second branches (81-8M) arranged to be capable of connecting the first and second nodes (3,4) by means of one or more second switches (Q21-Q2M) of the switches (Q11-Q1M, Q21-Q2M), wherein each second branch (81-8M) of said one or more second branches (81-8M) comprises a respective second switch (Q21-Q2M) of said one or more second switches (Q21-Q2M),
and wherein the control circuit (1) is provided with a number of connection lines (V1-VN) corresponding to at least a first count of the respective plurality of battery cells (C11-C1M),
wherein each connection line (V1-VN) of the number of connection lines (V1-VN) is arranged to parallelly connect a respective set (C11-C1M, C21-C2M, . . . , CN1-CNM) of corresponding battery cells (C11-CNM) to each other via a respective controllable over-current protecting component (S11-S1M, . . . , SN1-SNM) for each corresponding battery cell (C11-CNM) of the respective set of corresponding battery cells (C11-C1M, C21-C2M, . . . , CN1-CNM), wherein said each corresponding battery cell (C11-CNM) is comprised in a respective first branch (71-7M) of said at least two first branches (71-7M), and
wherein the corresponding battery cells of the respective set (C11-C1M, C21-C2M, . . . , CN1-CNM) of corresponding battery cells (C11-CNM) are corresponding to each other in that of a respective second count of battery cells towards the first or second node (3, 4) from said each corresponding battery cell in the respective first branch (71-7M) is equal.

2. The battery module (2) according to claim 1, wherein the control circuit (1) is configured to send a respective control signal (T1-TM) to a corresponding set of respective controllable over-current protecting components (S11-S1M, . . . , SN1-SNM), wherein the corresponding set of respective controllable over-current protecting components (S11-S1M, . . . , SN1-SNM) corresponds to said each first branch (71-7M) in that the corresponding set of respective controllable over-current protecting components (S11-S1M, . . . , SN1-SNM) comprises those respective controllable over-current protecting components (S11-S1M, . . . , SN1-SNM) for which said each corresponding battery cell (C11-CNM) is included in said each first branch (71-7M).

3. The battery module (2) according to claim 1, wherein the control circuit (1) is configured to receive a number of indications relating to voltage over each battery cell (C11-CN1, . . . , C1M-CNM) in a particular first branch (71-7M) by being configured to:
set the respective controllable over-current protecting component (S11-S1M, . . . , SN1-SNM) in said particular first branch (71-7M) to allow current through the respective controllable over-current protecting component (S11-S1M, . . . , SN1-SNM),
set the respective controllable over-current protecting component (S11-S1M, . . . , SN1-SNM) in other first branches (71-7M) but said particular first branch (71-7M) to open, whereby current through the respective controllable over-current protecting component (S11-S1M, . . . , SN1-SNM) is stopped.

4. The battery module (2) according to claim 1, wherein the control circuit (1) is configured to repeat the setting of the respective controllable over-current protecting component (S11-S1M, . . . , SN1-SNM) in said particular first branch (71-7M) and the setting of the respective controllable over-current protecting component (S11-S1M, . . . , SN1-SNM) in other first branches (71-7M) but said particular first branch (71-7M) for said each first branch (71-7M).

5. The battery module (2) according to claim 1, wherein the respective controllable over-current protecting component (S11-S1M, . . . , SN1-SNM) is configured to autonomously enter a latched state, in which the respective controllable over-current protecting component (S11-S1M, . . . , SN1-SNM) is in an open state, when a threshold value relating to current through the respective controllable over-current protecting component (S11-S1M, . . . , SN1-SNM) and/or relating to voltage over the respective controllable over-current protecting component (S11-S1M, . . . , SN1-SNM) is exceeded or reached.

6. The battery module (2) according to claim 1, wherein the control circuit (1) is configured to send a reset signal to the respective controllable over-current protecting component (S11-S1M, . . . , SN1-SNM), wherein the reset signal instructs the respective controllable over-current protecting component (S11-S1M, . . . , SN1-SNM) to be set in a closed state.

7. The battery module (2) according to claim 1, wherein said one or more second branches (81-8M) comprise at least two respective second branches (81-8M), wherein said at least two respective second branches (81-8M) comprise a respective second branch over-current protecting component (F21-F2M) connected in series with the respective second switch (Q21-Q2M) of said at least two second branches (81-8M).

8. The battery module (2) according to claim 1, wherein said at least two first branches (71-7M) comprise at least three first branches (71-7M).

9. The battery module (2) according to claim 1, wherein said each first branch (71-7M) comprises a respective first branch over-current protecting component (F11-F1M).

10. A battery pack (100) comprising a battery module (2) according to claim 1.
